(19) United States
(12) Patent Application Publication
(10) Pub. No.: US 2019/0199922 A1
(43) Pub. Date: Jun. 27, 2019

(54) CAMERA MODULE POWER SUPPLY

(71) Applicant: TRW Automotive U.S. LLC, Livonia, MI (US)

(72) Inventors: Nagender Reddy Kasarla, Farmington Hills, MI (US); Karteek Kesavamatham, Novi, MI (US)

(21) Appl. No.: 15/851,772

(22) Filed: Dec. 22, 2017

(51) Int. Cl. H04N 5/232; H01L 35/28; H02J 7/00; B60R 16/033

(52) U.S. Cl. CPC H04N 5/23241; H01L 35/28; H02J 7/345; B60R 16/033; H02J 7/0068

(57) ABSTRACT

A camera module for a vehicle includes a camera unit and a thermo-electric converter for converting heat generated by the camera unit into electricity. An electric converter electrically connected to the thermo-electric converter selectively routes electricity generated by the thermo-electric converter to the camera unit.

### TECHNICAL FIELD

The present invention relates to a camera module and, more specifically, relates to a camera module that recycles heat generated by the camera module into an alternate power source for the camera module.

### BACKGROUND

Vehicle camera and sensor systems are used in a variety of applications to assist operation of the vehicle. The systems can include one or more printed circuit boards (PCB), software, sensors, wireless transmitters, and other electronic components to capture images of the vehicle surroundings to be subsequently processed and analyzed. The systems are powered by the vehicle and generate heat when in use.

### SUMMARY

In accordance with an aspect of the present invention, a camera module for a vehicle includes a camera unit and a thermo-electric converter for converting heat generated by the camera unit into electricity. An electric converter electrically connected to the thermo-electric converter selectively routes electricity generated by the thermo-electric converter to the camera unit.

In another aspect of the invention, a method of powering a camera module for a vehicle includes capturing heat generated by the camera module. The heat is converted into electricity. The electricity is used to power the camera module.

Other objects and advantages and a fuller understanding of the invention will be had from the following detailed description and the accompanying drawings.

### BRIEF DESCRIPTION OF THE DRAWINGS

FIG. 1 is a schematic illustration of a camera module in accordance with a first embodiment of the present invention.

FIG. 2 is a front view of a thermal energy storage device in the camera module of FIG. 1.

FIG. 3A is a top view of a thermoelectric converter in the camera module of FIG. 1.

FIG. 3B is a section view taken along line 3B-3B of FIG. 3A-3A.

FIG. 4 is a schematic illustration of the thermoelectric converter of FIG. 3A.

FIG. 5 is a circuit diagram of a portion of the camera module of FIG. 1.

FIG. 6 is a schematic illustration of a camera module in accordance with a second embodiment of the present invention.

### DETAILED DESCRIPTION

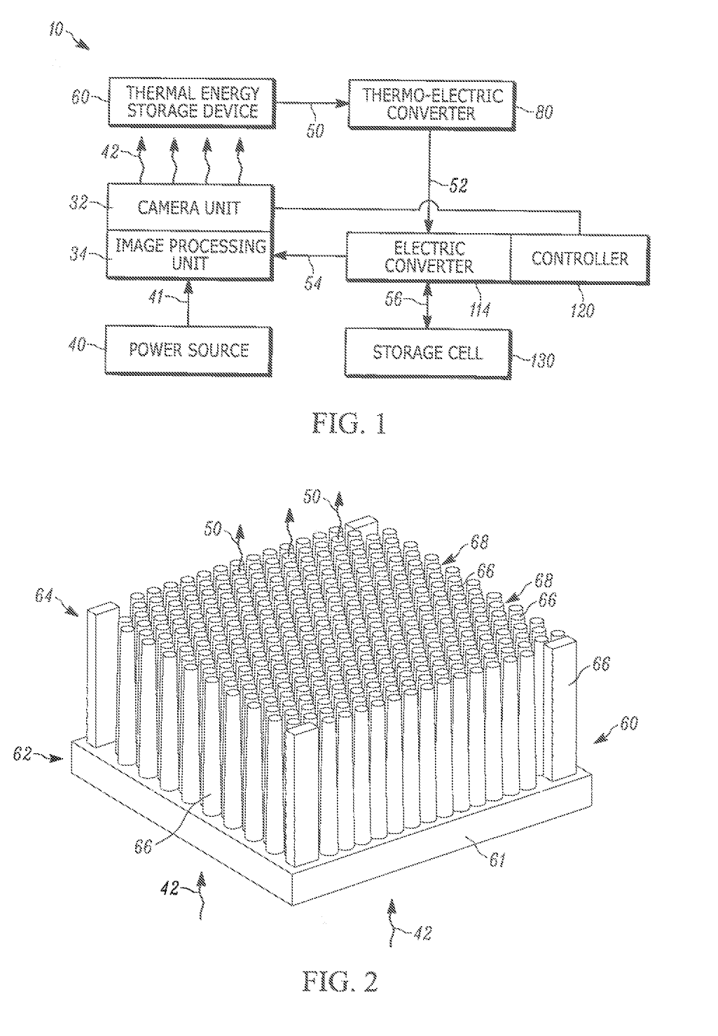

The present invention relates to a camera module and, more specifically, relates to a camera module that recycles heat generated by the camera module into an alternate power source for the camera module. A camera module 10 in accordance with the present invention is shown in FIG. 1. In one example, the camera module 10 is part of a vehicle electronics system, such as an advanced driver-assistance (ADAS) system. The camera module 10 includes a vehicle camera unit 32, such as a front camera unit, a rear camera unit and/or side camera unit. The camera unit 32 includes an image processing unit 34 for acquiring and processing image data from the camera unit to help the driver operate a vehicle. The camera unit 32 can include one or more printed circuit boards (PCB), image processing chips, RF transceivers, sensors, analog circuitry, controller(s), and other electronic components interconnecting the same (not shown).

A primary power source 40 supplies electrical signals 41 to the camera unit 32. The primary power source 40 can be the vehicle battery. When the camera unit 32 operates, its components, e.g., the image processing unit 34, generate heat, indicated generally by the arrows 42, that radiates outward from the module. The camera module 10 includes a series of components for converting or recycling the heat 42 into an alternate or backup power source for the camera module. In other words, the heat 42 can be repurposed into electricity for operating the camera unit 32.

The camera module 10 includes a thermal energy storage device or module 60 positioned within the path of the radiated heat 42 for capturing and dissipating the generated heat. The thermal energy storage module 60 can constitute a sensible heat storage module (when the generated heat 42 is expected to be variable) or a latent heat storage module (when the generated heat is expected to be constant or substantially constant). Whether the thermal energy storage module 60 is of the sensible heat or latent heat construction depends on the operating nature of the camera unit 32, e.g., constant or variable. The thermal energy storage module 60 can be, for example, a heat sink, metal cover or thermal pad capable of capturing and dissipating heat generated by the camera unit 32.

As shown in FIG. 2, the thermal energy storage module 60 is a heat sink. The heat sink 60 extends from a first end 62 to a second end 64. The heat sink 60 includes a base 61 at the first end 62. A plurality of projections or fins 66 extends away from the base 61 to the second end 64. The projections 66 are arranged in an array about the base 62 and extend parallel to one another. The projections 66 are spaced apart from one another by gaps or passages 68 filled with air. The projections 66 can be the same or different from one another in length, cross-section, etc. The heat sink 60 is formed from a material having high thermal conductivity, e.g., a metal such as aluminum.

The base 62 of the heat sink 60 is positioned adjacent the camera unit 32 in the direct path of the heat 42. Heat 42 emanating from the camera unit 32 strikes the base 61 and is conducted therethrough to the projections 66. The heat 42 then radiates from the projections 66 into the passages 68, ultimately being directed away from the second end 64 of the heat sink 60 in the manner indicated by the arrows 50.

A thermo-electric converter or generator 80 (FIG. 1) is positioned adjacent the second end 64 of the heat sink 60 and in the direct path of the heat 50. The thermo-electric converter 80, also known as a Seebeck generator, is a solid state device that converts heat flux directly into electricity via the Seebeck effect. The thermo-electric generator 80 is a solid state module designed to provide DC power over a high number of thermal cycles. The thermo-electric generator 80 has a continuous hot side operation capability that can exceed 200° C. Example thermo-electric generators for use in the present invention are sold by II-VI Marlow of Dallas, Tex., e.g. thermoelectric generator module TG12-2.5-01LS.

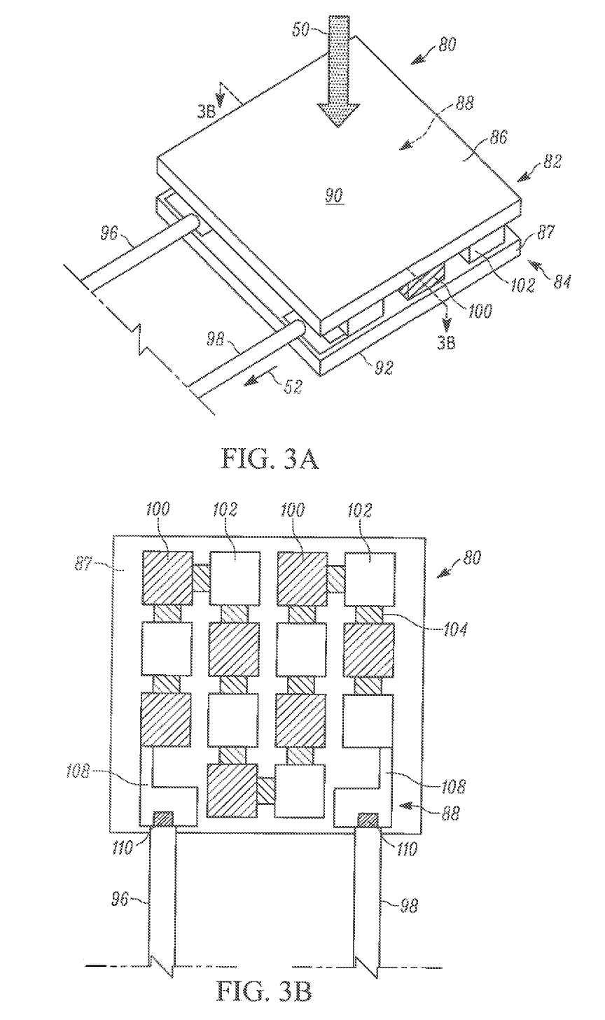

In one example shown in FIGS. 3A-3B, the thermoelectric generator 80 is composed of materials of different Seebeck coefficients configured as a thermoelectric circuit. The Seebeck coefficient of a material or device is its ability to generate a voltage per unit of temperature (stated in V/° C.). The thermal-electric generator 80 extends from a first side or end 82 to a second side or end 84. The thermal-electric generator 80 includes a dielectric substrate formed from a pair of spaced-apart plates 86, 87 defining an interior space 88. The plates 86, 87 can be made from, for example, ceramic, and define a pair of opposing, outer surfaces 90, 92 facing away from one another.

A series of semiconductor elements 100, 102 are secured to the substrate 86 within the interior space 88. The semiconductor elements 100 are P-type semiconductor pellets. The semiconductor elements 102 are N-type semiconductor pellets. The semiconductor elements 100, 102 are electrically connected to one another in series by conductor strips 104. A negative terminal wire 96 is secured via solder, adhesive, etc. at 110 to a conductor tab 108 electrically connected to one of the N-type semiconductor elements 102. A positive terminal wire 98 is secured via solder, adhesive, etc. at 110 to a conductor tab 108 electrically connected to one of the P-type semiconductor elements 100. The semiconductor elements 100, 102 are thermally connected in parallel with one another. The semiconductor pellets 100, 102 can be, for example, bismuth telluride or antimony telluride. The substrate 86 can be formed from, for example, aluminum oxide.

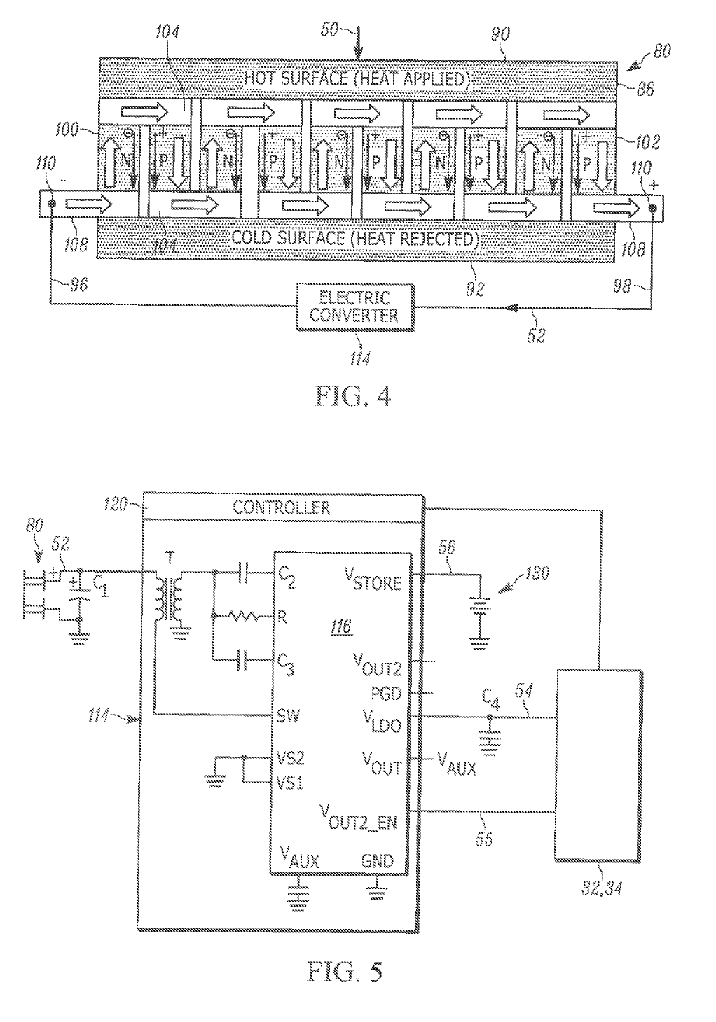

The thermo-electric converter 80 forms a circuit (shown in FIG. 4) that generates electricity directly from heat. As noted, the two dissimilar thermoelectric materials, namely, the N-type semiconductor elements 100 and the P-type semiconductor elements 102, are electrically joined at their ends to the negative terminal wire 96 and the positive terminal wire 98, respectively. A dielectric current will flow in the circuit when there is a temperature difference between the two semiconductor elements 100, 102 that exceeds a predetermined threshold, e.g., from about 1° C.-5° C. The current magnitude is generally proportional to the temperature difference between the semiconductor elements 100, 102 and, thus, the greater the temperature difference, the higher the output current produced.

With this in mind, the surface 90 of the substrate 86 is aligned with and in close proximity to the second end 64 of the heat sink 60. Consequently, the heat 50 exiting the heat sink 60 strikes the surface 90 of the substrate 86. The heat 50 conducts through the substrate 86, thereby creating a thermal gradient between the surfaces 90, 92. As a result, a dielectric current is generated and is output from the thermo-electric converter 80 as a signal represented generally by the arrows 52 in FIG. 4.

The thermal-electric converter 80 is electrically connected to an electric converter 114. In one example, the electric converter 114 is a DC-to-DC converter for converting the incoming signal 52 from one voltage to another. Referring to FIG. 5, the electric converter 114 can include an integrated circuit (IC) 116 and a transformer T to perform step-up conversion of the incoming signal 52 on the order of, for example, 1:100. The IC 116 contains components (not shown) for setting the input-to-output ratios of the electric converter 114.

A capacitor C₁ can be provided between the thermo-electric converter 80 and the electric converter 114 for filtering the incoming signal 52. A capacitive-resistive network C₂-R-C₃ receives an input from the transformer T and provides a desired output signal to the IC 116. A secondary winding SW of the transformer T feeds a charge pump and rectifier circuit (not shown) used to power the IC 116 via a V_{AUX} pin.

The electric converter 114 includes a series of outputs electrically connected to the camera unit 32 for sending electrical signals 54, 55 thereto. A V_{LDO} pin is designed to be in regulation first for powering a low power microprocessor on board the camera unit 32 as soon as possible. For instance, the V_{LDO} pin can be used to provide a signal 54 to the camera unit 32 during start-up thereof, which can last about 10 ms.

A main output capacitor C₄ of the converter 114 is charged to the voltage programmed by VS₁ and VS₂ pins, e.g., 2.35 V, 3.3 V, 4.1 V or 5.0 V, for powering sensors, analog circuitry, RF transceivers, etc. on the camera unit 32 via the signal 54. A V_{OUT} reservoir capacitor supplies burst energy required during the low duty cycle pulse when any sensors in the module 30 are active and transmitting. A switched output V_{OUT2}_{_}_{EN} pin is controlled by the camera unit 32 and outputs a signal 55 for powering circuits on the camera unit that do not have a shutdown or lower power sleep mode. A power good output PGD pin alerts the module 30 that the main output voltage of the converter 114 is close to its regulated value.

A V_{STORE} pin is electrically connected to a storage cell 130 for selectively storing the electric output of the thermo-electric generator 80. More specifically, the V_{STORE} pin sends a signal 56 to the storage cell 130 in lieu of or in addition to sending the signals 54 and/or 55 to the module 30. The storage cell 130 can be, for example, a rechargeable battery or capacitor. The V_{STORE} pin is electrically connected to the V_{LDO}, V_{OUT}, and V_{OUT2}_{_}_{EN} pins within the electric converter 114 to electrically connect the storage cell 130 to the camera unit 32.

Based on this construction, the electric converter 114 receives a time variable, DC signal 52 from the thermo-electric converter 80 and supplies a time invariable DC signal to the storage cell 130 [as a signal 56] and/or to the module 30 [as signal 54 and/or signal 55]. A controller 120 determines whether the incoming signal 52 is directed to the camera unit 32 or the storage cell 130. The controller 120 can be integrated into the electric converter 114 or be a stand-alone unit (not shown) electrically connected to the converter. In any case, the controller 120 monitors the power level demand of the primary power source 40 and the amount of power stored in both the primary power source and the storage cell 130. The controller 120 performs calculations/algorithms, etc. and, when appropriate or desirable, determines which power source 40 or 130 powers the camera unit 32. Consequently, the storage cell 130 can be a backup or alternate power source for the camera unit 32.

Referring to FIG. 1, during normal operation of the vehicle, the controller 120 generally relies on the primary power source 40 to power the camera unit 32. When the primary power source 40 is used, the controller 120 ensures that any electricity generated by the heat 40 is routed to the storage cell 130. More specifically, the heat 40 is converted by the thermo-electric converter 80 into an electrical signal 52, which is converted by the electric converter 114 into the signal 56 and routed through the V_{STORE} pin to the storage cell 130. This provides a stored surplus of electricity for selectively powering the camera unit 32.

The circumstances surrounding operation of the camera unit 32 can change over time. For example, a faulty electrical connection can exist between the camera unit 32 and the primary power source 40. There could also be insufficient power stored in or accessible from the primary power source 40, e.g., the vehicle is not running.

The particulars and timing of the camera unit 32 operation can also change over time. In certain instances the camera unit 32 may not require constant power for operation and/or may only be active for a short duration. In response to these considerations, the controller 120 can prevent the transmission of the signal 41 between the primary power source 40 and the camera unit 32 and initiate the transmission of the signal 54 and/or the signal 55 from the electric converter 114 to the camera unit.

When it is desirable to rely on the stored electricity in the storage cell 130 to generate the signals 54, 55, the controller 120 routs power from the storage cell 130, through the V_{STORE} pin, through the IC 116, and to the module 30 through one or both of the V_{LDO} pin and V_{OUT2}_{_}_{EN} pin. The controller 120 may determine, for example, that it is desirable to rely on the storage cell 130 to power the camera unit 32 during the wakeup phase of the camera module 10, which can be about 10 ms in duration and utilizes a small amount of power.

Stored electricity within the storage cell 130 can be used to maintain regular operation of the IC 116 and the camera unit 32, even when the heat generated by the camera unit is intermittent and/or insufficient to generate the signal 52. In other words, the storage cell 130 can maintain power to the IC 116 and the camera unit 32 even when the camera unit does not run continuously and/or does not generate heat sufficient for the electric converter 80 to produce the signal 52. Some camera unit 32 applications operate continuously instead of having a pulsed load. When the power demand of the continuous application is below a predetermined threshold, the storage cell 130 can continuously power the camera unit 32 with the recycled thermal energy.

The controller 120 can alternatively bypass the storage cell 130 by directly generating the signals 54, 55 from the incoming signal 52. Since the camera unit 32 may not be continuously in use, they will not continuously generate heat 42 to be converted into the signal 52. Consequently, the controller 120 can periodically rely on the storage cell 130 to supplement the incoming signal 52 to ensure an adequate power supply to the camera unit 32.

The controller 120 can advantageously switch between using the primary power source 40 and the recycled thermal energy throughout use of the camera unit 32 and operation of the vehicle. For example, as shown in FIG. 5, the camera unit 32 is powered by the V_{LDO} pin. When the controller 120 determines the camera unit 32 requires a low power demand, e.g., during startup, the controller briefly electrically connects the storage cell 130 to the V_{LDO} pin to supply the camera unit with power. Once the operation is performed, the controller 120 routes power from the primary power source 40 to the camera unit 32.

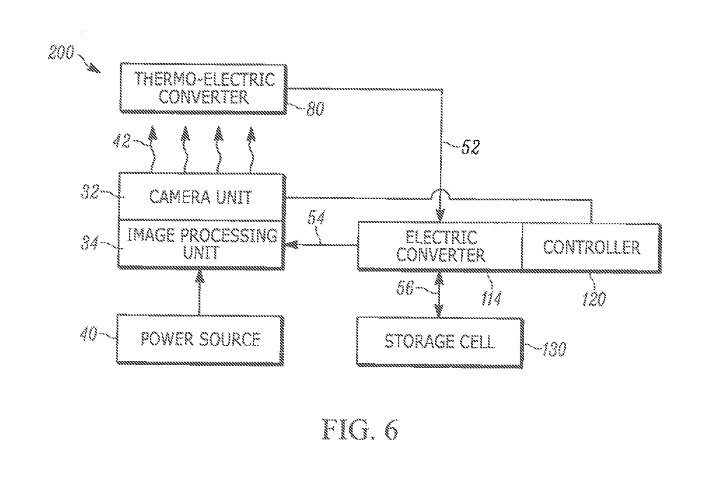

FIG. 6 illustrates another example camera module 200. In FIG. 6, elements that are the same as the corresponding element in FIG. 1 are given the same reference numeral. In the camera module 200, the thermal energy storage device 60 is omitted and, thus, heat 40 radiated from the module 30 flows directly into the thermo-electric converter 80 to be converted into the electrical signal 52. The signal 52, in turn, is converted by the electric converter 114 and routed to the storage cell 130 and/or to the camera unit 32. Absent the omission of the thermal energy storage module 60, the operation of the camera module 200 is the same as operation of the camera module 10 previously described.

The present invention is advantageous because heat generated by operating the camera unit, e.g., by the image processing unit, that is otherwise lost to the environment is instead recycled as an additional power source for the camera module. This additional power source can be used in lieu of or in addition to the primary power source, typically the vehicle battery. The controller in the present invention monitors operation of the camera module and determines when it is desirable to rely on the recycled thermal energy to power the camera module.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A camera module for a vehicle, comprising:
a camera unit;
a thermo-electric converter for converting heat generated by the camera unit into electricity; and
an electric converter electrically connected to the thermo-electric converter for selectively routing electricity generated by the thermo-electric converter to the camera unit.

2. The camera module recited in claim 1 further comprising a storage cell electrically connected to the electric converter for storing electricity generated by the thermo-electric converter.

3. The camera module recited in claim 2, wherein the electric converter routes electricity from the storage cell to the camera unit when the camera unit is not generating heat.

4. The camera module recited in claim 2, wherein the electric converter routes electricity from the storage cell to the camera unit during start-up of the camera module.

5. The camera module recited in claim 2, wherein the storage cell comprises a rechargeable battery.

6. The camera module recited in claim 1, wherein the storage cell comprises a capacitor.

7. The camera module recited in claim 1, wherein the electric converter includes an integrated circuit for routing electricity from the thermo-electric generator to the camera unit and a transformer for increasing the voltage of the electricity from the thermo-electric generator.

8. The camera module recited in claim 7, wherein the transformer increases the voltage by a factor of 100.

9. The camera module recited in claim 1 further comprising a thermal energy storage module for capturing heat generated by the camera unit and electrically connected to the thermo-electric converter.

10. The camera module recited in claim 9, wherein the thermal energy storage module comprises a heat sink including a plurality of projections for directing heat towards the thermo-electric generator.

11. The camera module recited in claim 1 further comprising:
a thermal energy storage device for capturing heat generated by the camera unit; and
a storage cell electrically connected to the thermo-electric converter for storing electricity generated by the thermo-electric converter.

12. The camera module recited in claim 1 further comprising a controller for monitoring a power demand of the camera unit and, in response thereto, routing electricity generated by the thermo-electric converter to the camera unit.

13. The camera module recited in claim 12 further comprising a storage cell electrically connected to the converter for storing electricity generated by the thermo-electric converter, the controller, in response to monitoring the power demand of the camera unit, routing electricity from the storage cell to the camera unit.

14. The camera module recited in claim 1 further comprising an image processing unit connected to the camera unit.

15. A method of powering a camera module for a vehicle comprising the steps of:
capturing heat generated by the camera module;
converting the heat into electricity; and
using the electricity to power the camera module.

16. The method recited in claim 15 further comprising converting the electricity from a first voltage to a second voltage greater than the first voltage.

17. The method recited in claim 15, wherein the electricity is used to power a camera unit of the camera module.

18. The method recited in claim 17 further comprising monitoring a power demand of the camera unit and, in response thereto, routing the converted electricity to the camera unit.

19. The method recited in claim 17 further comprising:
storing the electricity converted from heat in a storage cell; and
monitoring a power demand of the camera unit and, in response thereto, routing the stored electricity to the camera unit.

20. The camera module recited in claim 19, wherein the stored electricity is routed to the camera unit during start-up of the camera unit.
